(19) United States
(12) Patent Application Publication
(10) Pub. No.: US 2006/0113602 A1
(43) Pub. Date: Jun. 1, 2006

(54) MOS circuit arrangement

(76) Inventors: Cheng-Yu Fang, Hsinchu (TW); Wei-Jung Chen, Hsinchu (TW); Sheng-Ti Lee, Hsinchu (TW); Chien-Peng Yu, Hsinchu (TW); Yi-Cheng Wang, Hsinchu (TW)

Correspondence Address: ADVANCED ANALOG TECHNOLOGY, INC., 2F, NO. 17, INDUSTRY E. 2ND RD., SCIENCE-BASE INDUSTRIAL PARK, HSINCHU, 300, TW

(21) Appl. No.: 10/999,722

(22) Filed: Nov. 29, 2004

(51) Int. Cl. H01L 29/94

(52) U.S. Cl. 257/368

(57) ABSTRACT

A MOS circuit arrangement includes a silicon substrate, a semiconductor device, a field oxide layer, and a poly-protective layer. The silicon substrate has a conductive doping incorporated therein, wherein the semiconductor device is electrically connected with the silicon substrate. The field oxide layer is formed on the silicon substrate at a position spaced apart from the terminal of the semiconductor device to form an active region between the field oxide layer and the semiconductor device. The poly-protective layer deposited on the active region to communicate the field oxide layer with the terminal of the semiconductor device, wherein the poly-protective layer provides a junction breakdown path between the semiconductor device and the silicon substrate to increase a junction breakdown voltage of the semiconductor device.

### BACKGROUND OF THE PRESENT INVENTION

1. Field of Invention

The present invention relates to a semiconductor, and more particularly to a Metal Oxides Semiconductor (MOS) circuit arrangement which is capable of increasing a junction breakdown voltage of the relevant semiconductor.

2. Description of Related Arts

Referring to FIG. 1 of the drawings, a conventional NMOS circuit arrangement is illustrated. Typically, the NMOS circuit arrangement comprises a semiconductor device 10P, such as a sensor or a predetermined combination of such typical semiconductor electronics as MOS transistors, a substrate 20P of a predetermined type, such as a P-well substrate, and a Field Oxide (FOX) Layer 30P which is typically utilized to isolate two of the adjacent semiconductor devices 10P.

During a typical manufacturing process for the NMOS circuit arrangement, a technique known as wet oxidation has been widely utilized for forming the FOX layer 30P, wherein the NMOS circuit arrangement is exposed to oxygen rich environment. However, in that oxygen rich environment which forms the FOX layer 30P, there usually exist lateral diffusions between oxygen and the liquid molecules which may eventually produce a tapering oxide layer formed on the semiconductor device 10P. This layer of tapering oxide is generally known as bird's bead which, due to residual stress developed therewithin during the oxidation process, is likely to contain defective or spontaneously damaged structure. This random defective structure—which is generally called “punch-through” effect among those skilled in the art, inevitably affects the overall performance of the entire MOS circuit arrangement and decreases the life-span of the utility application in which this MOS circuit arrangement implements. As a matter of conventional art, the possibility of punch-through occurring is particularly high in very small scale transistors, because a lower impurity concentration usually occurs in the vicinity of the source and drain depletion regions of the relevant transistors.

As a result, methods of preventing this “punch through” problem have frequently been developed. For example, considerable efforts have been devoted to increase the impurity concentration in the vicinity of the source and drain depletion regions of the relevant semiconductors. A typical impurity is boron which is applied to P-field implant wherein a particularly high concentration of this impurity is usually applied in the vicinity of semiconductor device 10P—FOX layer 30 junction. However, while this type of methods is theoretically possible, it is difficult to achieve a consistent and reliable performance of the increased breakdown voltage since in a sophisticated MOS circuit arrangement, each different semiconductor has different electrical characteristics, therefore an invariable increase in boron concentration for all semiconductors may render some of them improperly operating and, as a result, ultimately affecting the overall performance of the entire MOS circuit arrangement.

Similarly, for conventional PMOS circuit arrangement, a higher concentration of phosphorous is usually applied at the silicon semiconductor device 10—FOX 30 junction to increase breakdown voltage. Here, the problems are similar to that of the NMOS.

Thus one is facing a tension of punch through problem and breakdown voltage problem. The conventional arts are less than satisfactory in striking a well balance, not to mention resolving both problems at all.

On the other hand, referring to FIG. 2 of the drawings, a typical path of an Integrated Circuit (IC), such as a MOS circuit arrangement, is illustrated. Conventionally, MOS technology, especially submicron CMOS IC, is extremely vulnerable to electrostatic discharge (ESD) the existence of which is due to a wide range of reasons. As a result, there exist some sorts of ESD protection circuit which are aimed for blocking ESD from reaching the relevant semiconductors.

A main disadvantage of these ESD protection circuits is that they usually take up considerable amount of circuit area. In an information era in which everyone is pursuing smaller and smaller electronics equipments, these ESD protection circuits present a major barrier for further reducing the physical size of MOS circuit arrangement and therefore indirectly prevent electronic equipments from being further decreased in size.

Thus, ESD protection circuits, while electronically feasible for blocking ESD within a semiconductor IC, is regrettably not ideal for practical purpose, and even rapidly obsolete in an era which requires smaller and faster electronic devices.

### SUMMARY OF THE PRESENT INVENTION

A main object of the present invention is to provide a MOS circuit arrangement which is capable of increasing a junction breakdown voltage of a semiconductor device while at the same time prevent punch-through effect thereof.

Another object of the present invention is to provide a MOS circuit arrangement which comprising a poly-protective layer which substitutes conventional space-occupying ESD circuit for blocking ESD within the MOS circuit arrangement, thus significantly reducing a physical size of the present invention, or the equipment in which the present invention is incorporated.

Another object of the present invention is to provide a MOS circuit arrangement which does not involves complicated circuits for increasing breakdown voltage as well as minimizing punch-though problem. Thus, the present invention can be manufactured with minimum cost and therefore enjoying low ultimate selling price of consumers.

Another object of the present invention is to provide a MOS circuit arrangement which may be embodied as either a NMOS circuit arrangement or a PMOS circuit arrangement so as to maximize compatibility of the present invention to a wide variety of MOS circuits and applications.

Accordingly, in order to accomplish the above objects, the present invention provides a Metal Oxide Semiconductor (MOS) circuit arrangement, comprising:

a silicon substrate having a conductive doping incorporated therein;

a semiconductor device, having a terminal, electrically connected with the silicon substrate;

a field oxide layer formed on the silicon substrate at a position spaced apart from the terminal of the semiconductor device to form an active region between the field oxide layer and the semiconductor device; and

a poly-protective layer deposited on the active region to communicate the field oxide layer with the terminal of the semiconductor device, wherein the poly-protective layer provides a junction breakdown path between the semiconductor device and the silicon substrate to increase a junction breakdown voltage of the semiconductor device.

These and other objectives, features, and advantages of the present invention will become apparent from the following detailed description, the accompanying drawings, and the appended claims.

### BRIEF DESCRIPTION OF THE DRAWINGS

FIG. 1 is a conventional NMOS circuit arrangement.

FIG. 2 is a conventional MOS circuit arrangement with electrostatic discharge (ESD) protection.

FIG. 3 is a NMOS circuit arrangement according to a preferred embodiment of the present invention.

FIG. 4 is a PMOS circuit arrangement according to the above preferred embodiment of the present invention.

FIG. 5 is a schematic diagram of the MOS circuit arrangement according to the above preferred embodiment of the present invention, illustrated that conventional ESD protection circuit may be substituted.

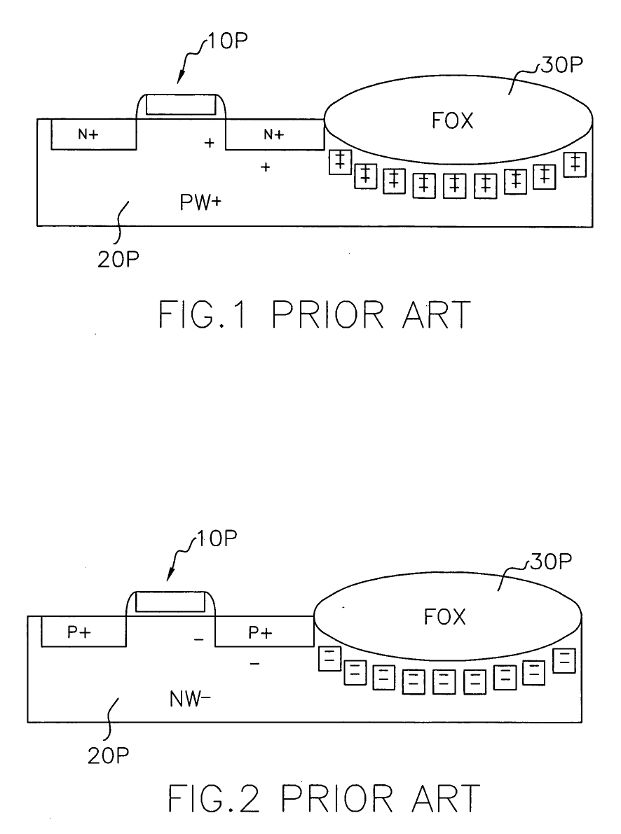

### DETAILED DESCRIPTION OF THE PREFERRED EMBODIMENT

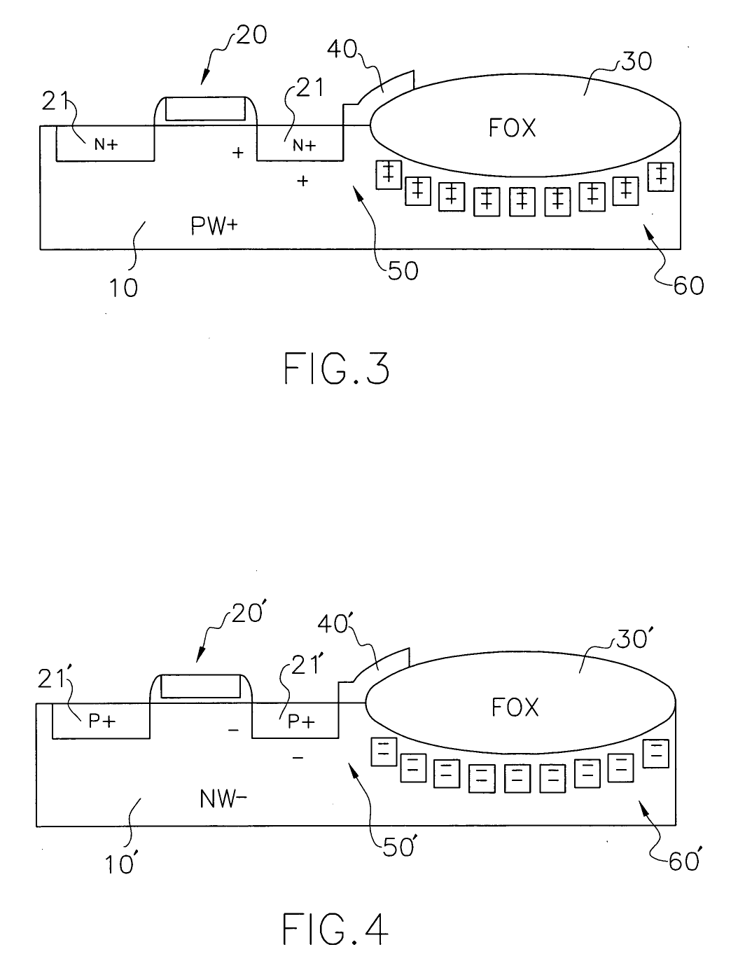

Referring to FIG. 3 of the drawings, a Metal Oxide Semiconductor (MOS) circuit arrangement according to a preferred embodiment of the present invention is illustrated, in which the MOS circuit arrangement comprises a silicon substrate 10, at least one semiconductor device 20, a Field Oxide (FOX) layer 30, and a poly-protective layer 40.

The silicon substrate 10 is primarily made of silicon which, after incorporating with certain kinds of conductive doping, would become semi-conducting with either type N or type P, i.e. having free negative electrons and positive electrons respectively. According to the preferred embodiment, the silicon substrate 10 may be either N-well substrate, P-well substrate, N substrate or P substrate. FIG. 3 mainly illustrates a P-well substrate. For example, phosphorus or arsenic is typically added to form a N substrate, whereas boron or gallium is usually added to form a P substrate.

The semiconductor device 20 is preferably embodied as a transistor, having at least one terminal 21, which is disposed on the silicon substrate 10 and is electrically connected thereto. According to the preferred embodiment, the transistor has a Gate terminal, a Drain terminal and a Source terminal, in which the terminal 21 is a N+ dopant and is embodied as either the Source terminal or the Drain terminal, thus forming a NMOS circuit arrangement. It is worth mentioning that other semiconductors are possible in forming the semiconductor device 20, such as a diode or a particular sensor.

The FOX layer 30 is formed on the silicon substrate 10 at a position spacedly apart from the terminal of the semiconductor device 20 to form an active region 50 between the FOX layer 30 and the semiconductor device 20. Moreover, the FOX layers 30 acts as an isolator for separating two or more semiconductor devices 20 in a MOS circuit arrangement for a particular semiconductor application.

The poly-protective layer 40 is deposited on the active region 50 to electrically communicate the FOX layer 30 with the terminal of the semiconductor device 20, wherein the poly-protective layer 40 provides a junction breakdown path between the semiconductor device 20 and the silicon substrate 10 to increase a junction breakdown voltage of the semiconductor device 20.

According to the preferred embodiment of the present invention, in order to prevent punch-through effect in the vicinity of the terminal of the semiconductor device 20 or the so-called N-P junction, a boundary between the N+ dopant terminal 21 and the silicon substrate 10, the MOS circuit arrangement further comprises a layer of impurity field implant 60 disposed in between the FOX layer 30 and the silicon substrate 10, and the active region, to electrically communicate the silicon substrate 10 and the semiconductor 20, in such a manner that a concentration of the impurity field implant 60 is elevated underneath the FOX layer 30 and in the vicinity of N-P junction as compared with other zones of the MOS circuit arrangement where the impurity field implant 60 is overlaid. As shown in FIG. 3 of the drawings, the impurity field implant 60 is preferably embodied as boron ions for a P-well substrate 10 in which an elevated concentration of the impurity field implant 60 can be observed in the vicinity of N-P junction.

In order to effectively manufacture the MOS circuit arrangement, the poly-protective layer 60 is overlaid on the silicon substrate 10, and of course the active region 50, before the semiconductor device terminal 21 (N+ dopant) is electrically mounted on the silicon substrate 10. Thus, the resulting electrical communication would be from the semiconductor device 21 to the impurity field implant at the N-P junction through the poly-protective layer 40.

It is then important to note that conventionally and without the poly-protective layer 40, a possible breakdown path for this particular NMOS circuit arrangement would be:

semiconductor device terminal 21 (N+ dopant)→silicon substrate 10 (P-well)+ impurity field implant 60 (P-type dopant) under the FOX

Experience reveals that the average breakdown voltage for this conventional circuit arrangement is approximately 10V.

However, with the overlay of the poly-protective layer 40, according to the preferred embodiment of the present invention, the breakdown path would instead be:

semiconductor device terminal 21 (N+ dopant)→poly-protective layer 40 (silicon substrate 10 (P-well))

It is expected that the resulting breakdown voltage would be increased to approximately 14V. One can appreciate that the increase in breakdown voltage would ultimately enhance the durability and performance of the entire MOS circuit arrangement.

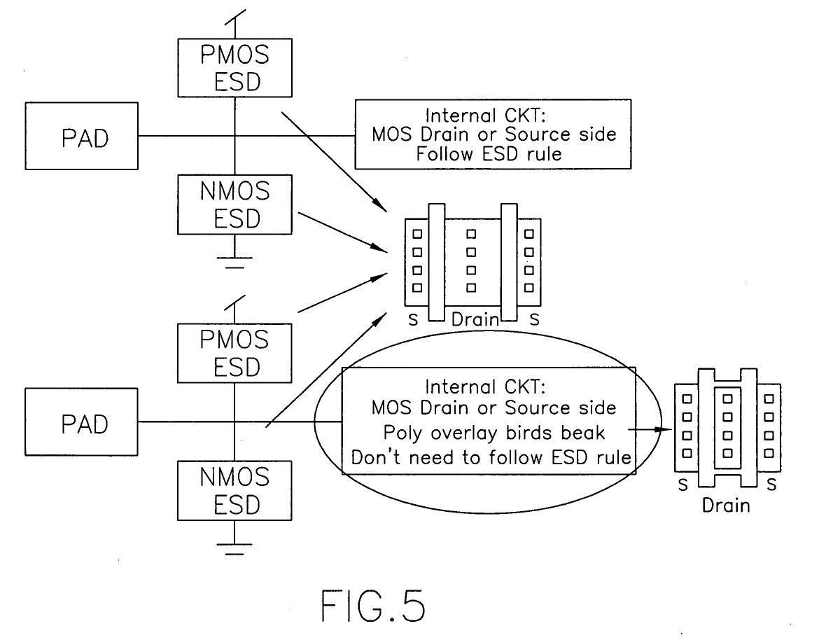

Referring to FIG. 4 of the drawings, an alternative mode of the present invention is illustrated, in which the silicon substrate 10′ is embodied as a N-well substrate, and that the semiconductor device terminal 21′ of the semiconductor device 20′ is P+ dopant forming a PMOS circuit arrangement of the present invention.

As in the above-mentioned preferred embodiment, the poly-protective layer 40′ is deposited on the active region 50′ to electrically communicate the FOX layer 30′ with the terminal of the semiconductor device 20′, wherein the poly-protective layer 40′ provides a junction breakdown path between the semiconductor device 20′ and the silicon substrate 10′ to increase a junction breakdown voltage of the semiconductor device 20′.

For this PMOS circuit arrangement, in order to prevent punch-through effect in the vicinity of the terminal of the semiconductor device 20′ or the N-P junction, a boundary between the P+ dopant terminal 21′ and the silicon substrate 10′, the impurity field implant 60′ is disposed in between the FOX layer 30′ and the N-well silicon substrate 10′ to electrically communicate the FOX layer 30′ and the semiconductor 20′, in such a manner that a concentration of the impurity field implant 60′ is also elevated underneath the FOX layer 30′ and in the vicinity of N-P junction as compared with other zones of the MOS circuit arrangement where the impurity field implant 60′ is overlaid. In this alternative mode, the impurity field implant 60′ is preferably embodied as phosphorus ions for the N-well substrate 10′ in which an elevated concentration of the impurity field implant 60′ can be observed in the vicinity of N-P junction, possibly due to segregation coefficient (m>1), a piping up effect under the FOX layer 30′.

Again, the poly-protective layer 60′ is overlaid on the active region 50′ before the semiconductor device terminal 21′ (P+ dopant) is electrically mounted on the silicon substrate 10′. Thus, the resulting electrical communication would be from the semiconductor device 21′ to the impurity field implant at the N-P junction through the poly-protective layer 40′.

It is therefore noteworthy that conventionally and without the poly-protective layer 40′, a possible breakdown path for this PMOS circuit arrangement would be:

semiconductor device terminal 21′ (P-type dopant)→silicon substrate 10′ (N-well)+impurity field implant 60′ (N-type dopant)

Experience reveals that the average breakdown voltage for this conventional circuit arrangement is approximately 10V.

However, with the overlay of the poly-protective layer 40′, according to the preferred embodiment of the present invention, the breakdown path would instead be:

semiconductor device terminal 21′ (P-type dopant)→poly-protective layer 40′ (silicon substrate 10 (N-well))

It is expected that the resulting breakdown voltage would be increased to approximately 13V. One can appreciate that the increase in breakdown voltage would ultimately enhance the durability and performance of the entire MOS circuit arrangement, a PMOS circuit arrangement in this particular alternative mode.

Referring to FIG. 5 of the drawings, a particular application of the MOS circuit arrangement of the present invention is illustrated. Specifically, the poly-protective layer 40′ is overlaid on the active region 50 (50′) between the Source terminal or the Drain terminal of a semiconductor, such as a transistor, and the respective FOX layer 30 (30′), so that Electrostatics Discharge (ESD) can be substantially blocked to minimize damage to the terminal 21 (21′) of the relevant semiconductor device 20 (20′), and ultimately to the entire semiconductor circuit.

As such, the use of ESD protection circuit can be substituted by overlaying of the poly-protective layer 40 (40′) on the above-mentioned active region 50 (50′) so as to avoid utilization of ESD protection circuit which is generally of significant space occupation in a particular MOS circuit.

From the forgoing descriptions, it can be shown that the above-mentioned objects are substantially accomplished. The present invention effectively provides a simple, economical and effective ways of blocking ESD in a typical MOS circuit, and creating a new breakdown path for semiconductor devices 20 (20′) so as to increase a breakdown voltage thereof.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

1-20. (canceled)

21. A Metal Oxide Semiconductor (MOS) circuit arrangement, comprising:
a silicon substrate having a conductive doping incorporated therein;
a semiconductor device, having a terminal region, formed in said silicon substrate;
a field oxide layer formed on said silicon substrate at a position spaced apart from said terminal region of said semiconductor device to form an active region between said field oxide layer and said semiconductor device;
a poly-protective layer overlaid on said active region; and
an impurity field implant region formed between said field oxide layer and said silicon substrate and adjacent said active region, in such a manner that said active region provides a breakdown path between said semiconductor device and said impurity field implant region to increase a breakdown voltage between said semiconductor device and said impurity field implant region.

22. The MOS circuit arrangement, as recited in claim 21, a concentration of said impurity field implant region is elevated underneath said field oxide layer and in a vicinity of a N-P junction of said terminal region and said substrate so as to prevent punch-through effect at said N-P junction.

23. The MOS circuit arrangement, as recited in claim 22, wherein said impurity field implant region is boron ions, having P-field implant, formed between said field oxide layer and said silicon substrate having said elevated concentration underneath said field oxide layer and in said vicinity of said N-P junction.

24. The MOS circuit arrangement, as recited in claim 21, wherein said terminal region of said semiconductor device is N-type dopant and is one of a Source terminal region and a Drain terminal region of said semiconductor device.

25. The MOS circuit arrangement, as recited in claim 23, wherein said terminal region of said semiconductor device is N-type dopant and is one of a Source terminal region and a Drain terminal region of said semiconductor device.

26. The MOS circuit arrangement, as recited in claim 21, wherein said silicon substrate is a P-well substrate.

27. The MOS circuit arrangement, as recited in claim 25, wherein said silicon substrate is a P-well substrate.

28. The MOS circuit arrangement, as recited in claim 21, wherein said active region is a P-well substrate.

29. The MOS circuit arrangement, as recited in claim 27, wherein said active region is a P-well substrate.

30. The MOS circuit arrangement, as recited in claim 21, wherein said impurity field implant region is phosphorus ions, having n-field implant, overlaid in between said field oxide layer and said silicon substrate having said elevated concentration underneath said field oxide layer and in said vicinity of said N-P junction.

31. The MOS circuit arrangement, as recited in claim 21, wherein said terminal of said semiconductor device is P-type dopant and is one of a Source terminal region and a Drain terminal region of said semiconductor device.

32. The MOS circuit arrangement, as recited in claim 30, wherein said terminal region of said semiconductor device is P-type dopant and is one of a Source terminal and a Drain terminal of said semiconductor device.

33. The MOS circuit arrangement, as recited in claim 21, wherein said silicon substrate is a N-well substrate.

34. The MOS circuit arrangement, as recited in claim 32, wherein said silicon substrate is a N-well substrate.

35. The MOS circuit arrangement, as recited in claim 21, wherein said active region is a N-well substrate.

36. The MOS circuit arrangement, as recited in claim 34, wherein said active region is a N-well substrate.

37. The MOS circuit arrangement, as recited in claim 21, wherein said poly-protective layer, is overlaid on said active region and said terminal region of said semiconductor device, and is capable of blocking Electrostatic Discharge (ESD) within said MOS circuit arrangement for avoiding use of electrostatic discharge protection circuit within said MOS circuit arrangement.

38. The MOS circuit arrangement, as recited in claim 29, wherein said poly-protective layer, is overlaid on said active region and said terminal of said semiconductor device, and is capable of blocking Electrostatic Discharge (ESD) within said MOS circuit arrangement for avoiding use of electrostatic discharge protection circuit within said MOS circuit arrangement.

39. The MOS circuit arrangement, as recited in claim 36, wherein said poly-protective layer, is overlaid on said active region and said terminal region of said semiconductor device, and is capable of blocking Electrostatic Discharge (ESD) within said MOS circuit arrangement for avoiding use of electrostatic discharge protection circuit within said MOS circuit arrangement.
